(19) United States
(12) Patent Application Publication
(10) Pub. No.: US 2010/0201003 A1
(43) Pub. Date: Aug. 12, 2010

(54) Packaging Systems Incorporating Thin Film Liquid Crystal Polymer (LCP) and Methods of Manufacture

(76) Inventors: Dane Thompson, Atlanta, GA (US); Guoan Wang, Atlanta, GA (US); Nickolas D. Kingsley, Atlanta, GA (US); Ioannis Papapolymerou, Decatur, GA (US); Emmanouil M. Tentzeris, Atlanta, GA (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 11/817,563

(22) PCT Filed: Nov. 23, 2005
(86) PCT No.: PCT/US05/42737

§ 371 Date: Aug. 31, 2007

Related U.S. Application Data
(60) Provisional application No. 60/657,814, filed on Mar. 2, 2005.

(51) Int. Cl. H01L 23/28; H01L 21/56

(52) U.S. Cl. 257/788; 438/127; 257/E23.116; 257/E21.502

(57) ABSTRACT

Packaging systems and methods of manufacture are provided. In this regard, a representative system comprises a first layer of liquid crystal polymer (LCP), a first electronic component supported by the first layer, and a second layer of LCP. The first layer and the second layer encase the first electronic component.

### CROSS REFERENCE TO RELATED APPLICATIONS

This application is based on and claims priority to U.S. Provisional Patent Application Ser. No. 60/657,814, filed on Mar. 2, 2005, which is incorporated by reference herein.

### STATEMENT REGARDING FEDERALLY SPONSORED RESEARCH

The U.S. government may (or does) have a paid-up license in this invention(s) and the right in limited circumstances to require the patent owner to license others on reasonable terms as provided for by the terms of NASA contract NCC3-1057.

### BACKGROUND

As RF systems' operating frequencies continue to rise, system reliability becomes increasingly reliant on hermetic or near hermetic packaging materials. Higher frequencies lead to several design challenges such as greater circuit sensitivity to tolerances (due to their smaller size), more difficult design of RF interconnects and package feedthroughs (due to high frequency parasitics), and greater sensitivity to packaging material characteristics (due to higher inherent material losses and absorbed water/oxygen contributions at higher frequencies). Low material expansion coefficients for packaging materials that are matched to the metals and/or semiconductors they are mated with are increasingly important as well since material expansion is also related to water absorption characteristics. Finally, moisture permeability should be minimized to maintain a stable dielectric constant and loss tangent.

The best packaging materials in terms of hermeticity are metals, ceramics, and glass. However, these materials often give way to cheaper polymer packages such as injection molded plastics or glob top epoxies when:
1) Cost is the driving factor
2) And when a package design with a known moisture permeability can be tolerated with the tradeoff of potentially shorter device failure time.
   Plastic packages are great for cost and ease of fabrication, but they are not very good at keeping out water and water vapor.

### SUMMARY

Packaging systems and methods of manufacture are provided. In this regard, an embodiment of such a system comprises a first layer of liquid crystal polymer (LCP), an electronic component supported by the first layer, and a second layer of LCP. The first layer and the second layer encase the first electronic component.

Another embodiment of such a system comprises: a first layer of liquid crystal polymer (LCP), the first layer being substantially planar; a first electronic component supported by and physically contacting the first layer; and a second layer of LCP having a cavity formed therein. The cavity is sized and shaped to receive at least a portion of the electronic component therein. The first layer and the second layer are arranged in an overlying relationship with respect to each other and fixed in position with respect to each other such that the first electronic component is near-hermetically sealed within the cavity, with the first electronic components being encased within the cavity by LCP of the first layer and the second layer.

An embodiment of a method comprises: providing a first layer and a second layer of liquid crystal polymer (LCP); supporting a first electronic component with the first layer; and encasing the first electronic component with the first layer and the second layer.

### BRIEF DESCRIPTION OF THE DRAWINGS

In the drawings, like reference numerals indicate corresponding components. Additionally, the drawings are not necessarily to scale.

FIG. 1 is a schematic diagram of an embodiment of a packaging system.

FIG. 2 is a flowchart of an embodiment of a method of manufacturing a packaging system.

FIGS. 3-5 are schematic cross sections three transmission lines.

FIG. 6 a circuit model of a transmission line.

FIG. 7 is a chart depicting a design for 20 GHz operation showing S₁₁ for cavities with electrical lengths from 0-360°.

FIG. 8 is a perspective view depicting an embodiment of an LCP packaging layer and a layer incorporating transmission lines and RF MEMS switches, with the layers also being shown stacked together for testing.

FIG. 9A is a perspective view depicting an embodiment of a packaging system at an intermediate processing step.

FIG. 9B is a perspective view depicting the embodiment of FIG. 9A after cleaning.

FIG. 10A is a perspective view depicting an embodiment of a packaging system at another intermediate processing step.

FIG. 10B is a perspective view depicting the embodiment of FIG. 10A after cleaning.

FIG. 11 is a schematic diagram of an embodiment of an RF MEMS switch.

FIG. 12 is a schematic diagram of a method of testing an embodiment of a packaging system.

FIG. 13 is a chart depicting comparison of S parameter measurements of an embodiment of an air-bridge type CB-FGC MEMS switch in the “UP” state.

FIG. 14 is a chart depicting comparison of S parameter measurements of an embodiment of an air-bridge type CB-FGC MEMS switch in the “DOWN” state.

FIG. 15 is a chart depicting comparison of S parameter measurements of an embodiment of a MEMS switch transmission line after the switch was physically removed.

FIGS. 16A-16C are schematic views of an embodiment of an RF MEMS switch during sequential manufacturing steps.

FIG. 17 is a chart depicting comparison of S parameter measurements of an embodiment of an air-bridge type switch in the “DOWN” state.

FIG. 18 is a chart depicting comparison of S parameter measurements of an embodiment of an air-bridge type switch in the “UP” state.

### DETAILED DESCRIPTION

As will be described in detail here, packaging systems and methods of manufacture are provided. In particular, such systems and methods involve the use of liquid crystal polymer (LCP). LCP exhibits a low dielectric constant and low loss tangent in tandem with low water absorption coefficient and low cost. Additionally, the coefficient of thermal expansion (CTE) of LCP can be adjusted, such as through thermal treatments, for example.

Solid state devices, such as pin diodes, have been packaged in LCP. In addition, several companies have recently developed injection molded LCP packaging caps, which can be used to seal individual components with epoxy or laser sealing. However, these packages can be bulky which may limit the packaging integration density. In addition, these rigid packaging caps (LCP becomes rigid when it has sufficient thickness) can take away one of the LCP substrates very unique characteristics—flexibility.

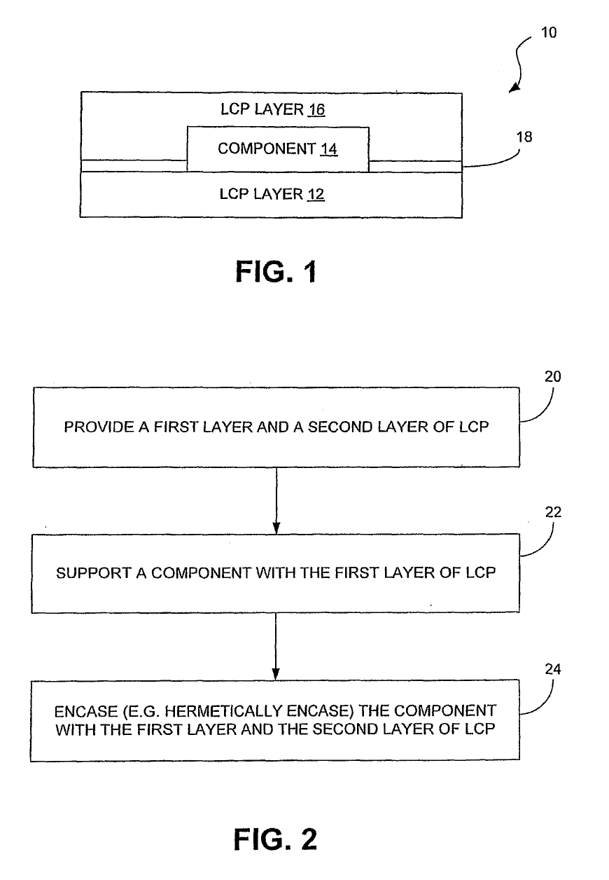

In this regard, an embodiment of a packaging system is depicted schematically in FIG. 1. As shown in FIG. 1, system 10 comprises a first layer of LCP 12 that is used to support an electronic component 14. By way of example, component 14 can be a switch, such as a MEMS switch. However, in other embodiments, various other electronic components, such as integrated circuits could be used.

A second layer 16 of LCP is then provided to encase the component 14. In some embodiments, as in this case, the first and second layers form a near-hermetic enclosure about the component 14. As used herein, the term “near-hermetic” means offering a hermetic seal over a limited, but substantial period of time. LCP's hermeticity has often been compared to that of glass which has a very low, but measurable permeability to moisture and gas. This corresponds to a package that could claim hermeticity for a number of years and satisfy the lifetime requirements for numerous applications. The barrier thickness would determine the time before some level of moisture and gas permeation pass through the barrier. The fluoropolymers like Teflon are the only polymers that compare similarly in terms of water permeability, but Teflon is worse than LCP in terms of gas permeability. In addition, LCP's multilayer lamination capability from the high and low melting temperature types allows for a unique capability of a sealed homogeneous LCP structure composed of the “near-hermetic” properties. Oxygen permeability rates for LCP are on the order of 0.02 [(cm³*mm)/(m²*day*atm)] and water permeability is on the order of 0.009 [(g*mm)/(m²*day)].

Notably, each of the layers is a thin-film LCP layer, thus, if desired, the material flexibility of the system may be retained by providing an appropriate overall thickness of the layers. If rigidity is desired, if taller cavities are required, or if lower package permeability is a goal, more thin-film layers may be laminated together to achieve the desired package characteristics and geometry.

In the embodiment of FIG. 1, the second layer 16 (the “LCP superstate layer”) is bonded to the first layer 12 with a low melting temperature LCP bond layer 18. Thus, packaging system 10 is an all LCP package. A seal is created by increasing the temperature of the layers until the low melting temperature LCP layer melts to adhere the layers. The layer 18, which has the same electrical characteristics as the layers 12 and 16, has a melting temperature of 290° C., whereas the layers 12 and 16 have melting temperatures of 315° C.

An embodiment of a method for manufacturing a packaging system, such as that of FIG. 1, is depicted in the flowchart of FIG. 2. As shown in FIG. 2, the method may be construed as beginning at block 20, in which a first layer and a second layer of LCP are provided. In block 22, a component is supported by the first layer. Then, in block 24, the component is encased, e.g. near-hermetically encased, by the first and second layers.

Since LCP has a low dielectric constant near 3.16 (close to free space εᵣ=1), impedance mismatches are minimal when an LCP superstrate layer is added on top of a standard transmission line. In addition, if cavities are machined in the superstrate layer, the cavities do not create large impedance mismatches at the cavity interface. Thus, LCP's low dielectric constant enables package cavities of arbitrary size to be integrated in a superstrate packaging layer to accommodate chips, MEMS, or other devices without concern for parasitic packaging effects.

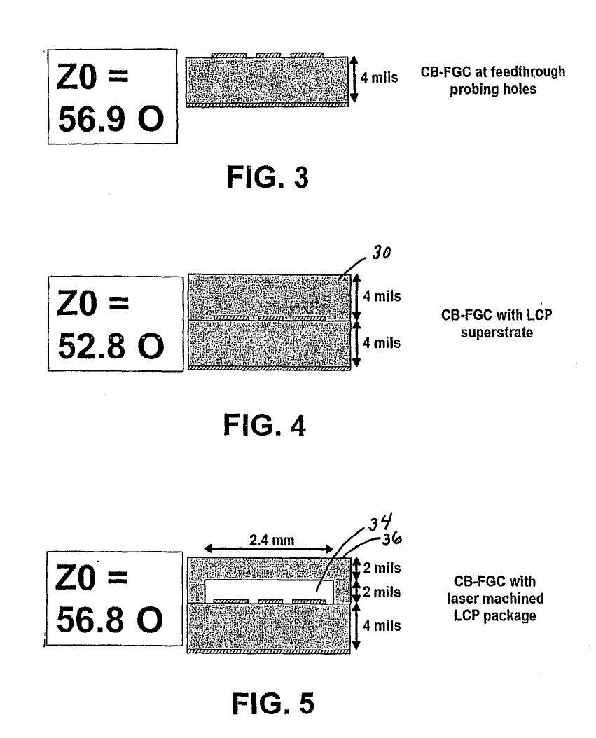

The RF characteristics of transmission lines with superstrate layers and various packaging cavities were investigated. In this regard, FIGS. 3-5 depict three different transmission line cross sections and the impedance differences there between. These cross sections were simulated and the impedance values were calculated with Ansoft HFSS. The cross section of FIG. 3 is a standard conductor-backed finite ground coplanar (CB-FGC) line, the cross section of FIG. 4 includes a 4 mil superstrate packaging layer 30, and the cross section of FIG. 5 includes a 2 mil laser machined cavity 34 in the superstrate layer 36.

The impedance difference between these simulations is 4Ω (see corresponding impedance adjacent each cross section). An impedance difference of only 4Ω between a transmission line with a superstrate layer versus those with a cavity (FIG. 5) or without a packaging layer (FIG. 3) creates minimal reflections at the dielectric discontinuity. Note that the impedance values are from HFSS 3D simulator for an CB-FGC with signal width S=200 μm, gap G=120 μm, and εᵣ=3.16 Z₀.

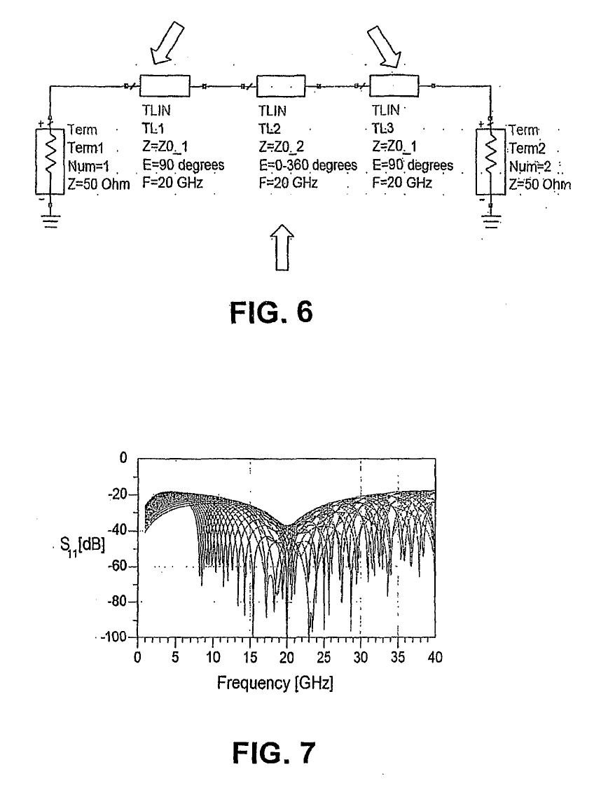

To determine the effects of varying the cavity dimensions, the impedance of each cross section of the embodiments of FIGS. 3-5 was found using Ansoft HFSS. These impedance values were input to an Agilent ADS and a circuit model (see FIG. 6) was simulated for 0-360° electrical length combinations of transmission lines with these impedance discontinuities. With Z₀=53Ω and 57Ω for the feeding and cavity segments respectively, the worst case value obtained for any combination of feed line lengths and cavity lengths is S₁₁=−17.7 dB. Most combinations yield S₁₁ below −20 dB and optimal transmission line length and cavity length combinations yield S₁₁ close to −40 dB. Because S₁₁ values less than −20 dB correspond to power reflection <1%, the package cavity size can be chosen almost at random to fit any desired device. FIG. 7 shows S₁₁ for cavities with electrical lengths from 0-360°. The CB-FGC in the cavity has Z₀=57Ω and the CB-FGC with superstrate feeding the cavity has Z₀=53Ω. The feeding CB-FGC lines are λ_{G}/4 at 20 GHz which is an optimal configuration for minimizing the already low reflections.

To demonstrate this capability, a 4 mil non-metallized LCP superstrate layer with depth-controlled laser micromachined cavities was constructed as a package. This technique is demonstrated by creating packages for air-bridge RF MEMS switches. The switch membranes are only about 3 μm above the base substrate which allows a cavity with plenty of clearance to be laser drilled in the LCP superstrate layer. A cavity depth of 2 mils (˜51 μm), half of the superstrate thickness, was chosen for the MEMS package cavities.

This technique could be extended to include additional layers as necessary. To accommodate devices that require more vertical clearance, multiple LCP layers could have holes or cavities formed therein, such as by drilling, and the layers stacked together. The packages can be sealed with thermo-compression, ultrasonic, or laser bonding, for example.

Several advantages of the above-mentioned technique are: the flexibility of the substrate may be maintained for applications such as conformal antennas, the package is light weight, and the LCP packaging layer is a standard inexpensive microwave substrate which can be made into any system-level package configuration. Two primary applications are large-scale antenna arrays with packaged ICs and/or switches inside of a multi-layer antenna substrate, or vertically integrated LCP-based RF modules where switches and/or active devices may be bonded inside of a multi-layer LCP construction.

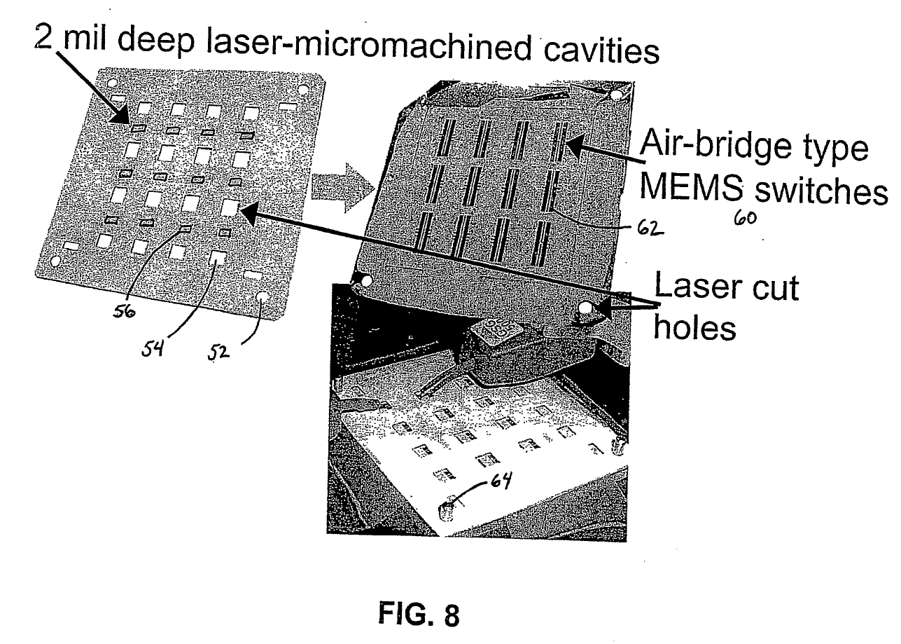

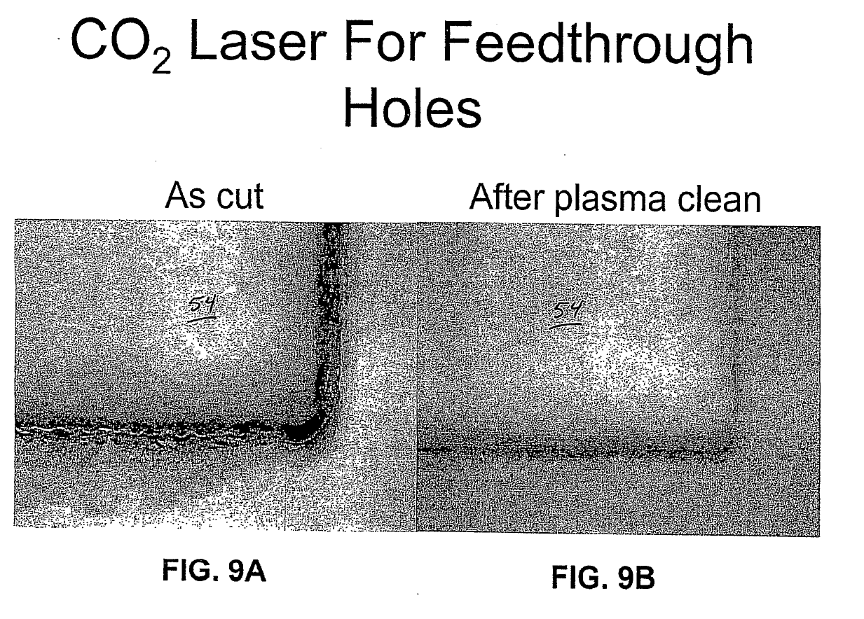

A CO₂ engraving laser with a 10 μm wavelength was used to form holes in the LCP superstrate layer (see FIGS. 8 and 9A). The CO₂ laser was selected due to its high power and the corresponding fast cutting rate. In particular, circles 52 were cut out in the four corners for pin alignment and square or rectangular windows 54 were removed in specified locations for the probe feed-throughs. The alignment holes and feed-through holes were drawn in AutoCAD, programmed into the laser software, and the cuts were made concurrently in a single laser run.

Due to surface irregularities caused during formation of the holes by the CO₂ engraving laser, a cleaning process was conducted. In particular, the LCP superstrate was cleaned by a plasma cleaning process to remove the irregularities as shown in FIG. 9B.

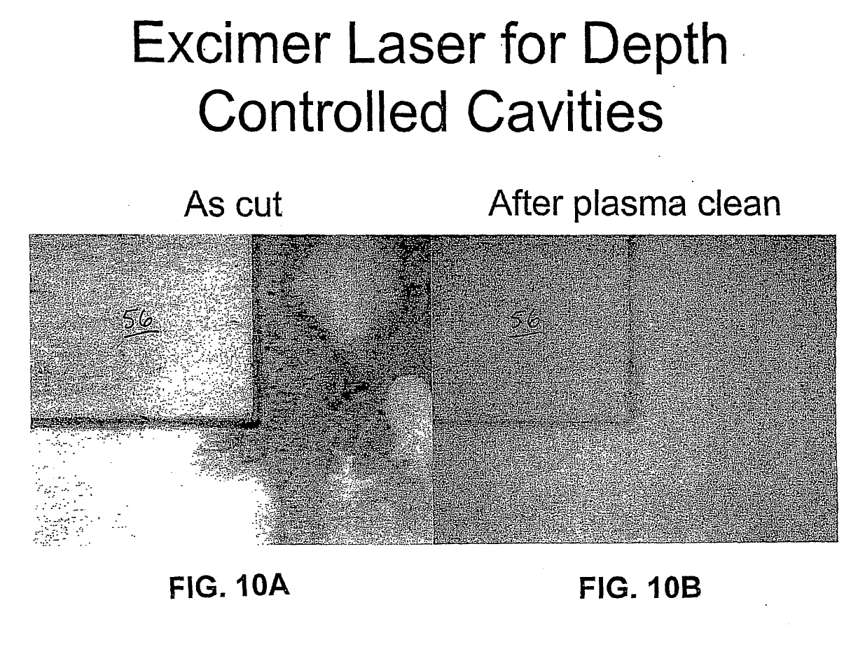

Next, an excimer laser was used to micromachine depth-controlled cavities 56 in the desired locations (see FIGS. 8 and 10A). The stage was aligned to the already cut holes from the CO₂ laser and the laser was again programmed to fire in a predetermined pattern. The optical alignment was limited by the large aperture size, but the accuracy was estimated to be within 100 μm at the worst case. The lateral cavity dimensions were chosen to be oversized enough that this potential alignment error was not a concern. With smaller apertures, alignment with the excimer laser of better than 10 μm can be accomplished.

The laser power and the number of pulses were tuned to provide the desired ablation depth into the LCP superstrate. We arbitrarily chose to make cavity depths half of the substrate thickness (2 mil deep cavities). Shallower or deeper cavities are possible by varying the laser power and the number of pulses. A custom brass aperture with a rectangular hole was used to shape the beam to the desired cavity shape and size. This aperture size of 12 mm×5 mm was demagnified five times to create a cavity 2.4 mm wide×1 mm long. After machining the cavities, the depth was checked with a microscope connected to a digital z-axis focus readout with accuracy to the nearest tenth of a micron. The depth across the bottom of the cavities was not completely uniform due to some small burn marks on the laser optics, but it was within ±5 microns of the desired depth across the entire cavity.

Due to surface irregularities caused during formation of the cavities by the excimer laser, a cleaning process was conducted. In particular, the LCP superstrate was cleaned by a plasma cleaning process to remove the irregularities as shown in FIG. 10B. This laser processing residue was less than 1 μm thick and cleaned in only a few minutes of the plasma cleaning process.

The completed package layers were made such that the alignment holes 52 corresponded to the same location as those on the through-reflect-line (TRL) calibration lines and also on the MEMS switch samples. Note in FIG. 8 that the packaged cavities between each set of probing holes are visible due to LCP becoming partially transparent at a 2 mil thickness. At the upper right portion of FIG. 8, CB-FGC transmission lines are visible with air-bridge RF MEMS switches 60 in the center of the transmission lines 62. Additionally, in the bottom right portion of FIG. 8, the package was aligned and stacked over the MEMS substrate with the assistance of four alignment pins 64 and probed through the feed-through windows.

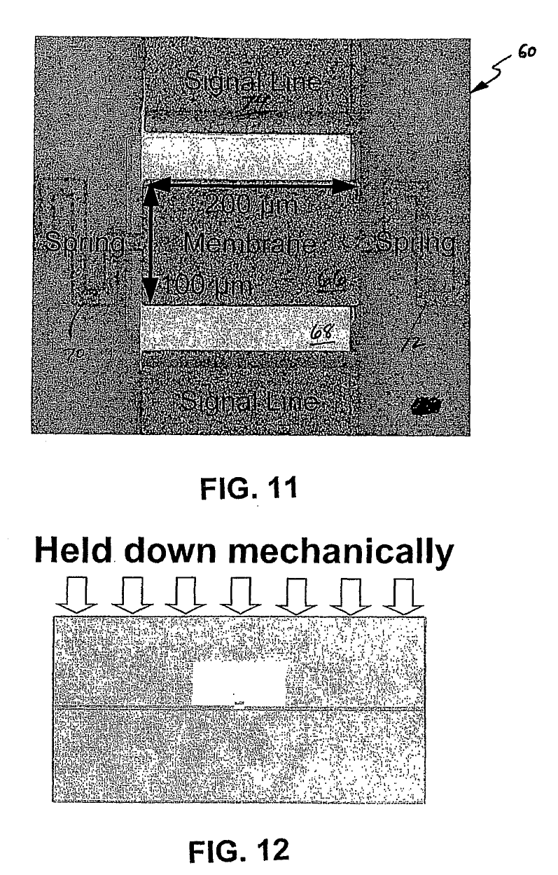

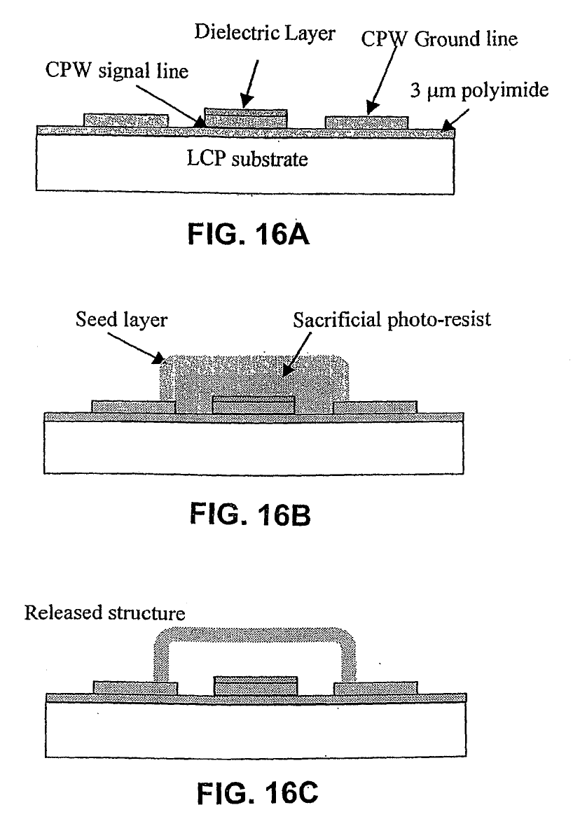

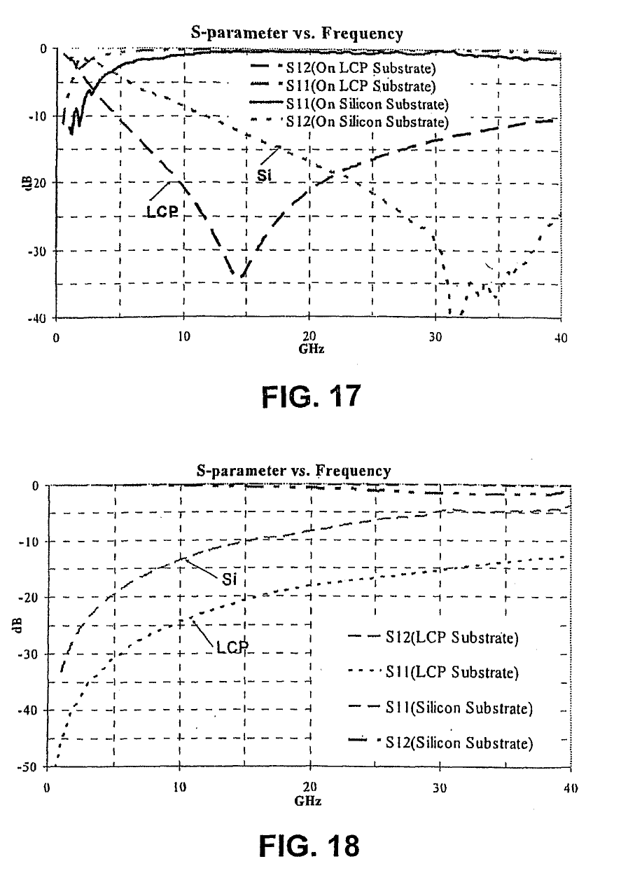

As shown in FIG. 11, each MEMS switch 60 is comprised of a 2 μm thick electroplated gold doubly-supported air-bridge layer 66 suspended by springs 70 and 72 approximately 3 μm above the lower metal layer 68. The 100×200 μm membrane is suspended over the signal line 74 of a CB-FGC transmission line and anchored to the ground planes on both sides. In the default state, the membrane is up, in which case full signal transmission should take place. When a DC actuation voltage is introduced, the membrane is flexed down into contact with a thin silicon nitride layer between the two metal layers and creates a capacitive short circuit that blocks signal transmission. Fabrication of an embodiment of an RF MEMS switch will be described later with respect to FIGS. 16A-17C.

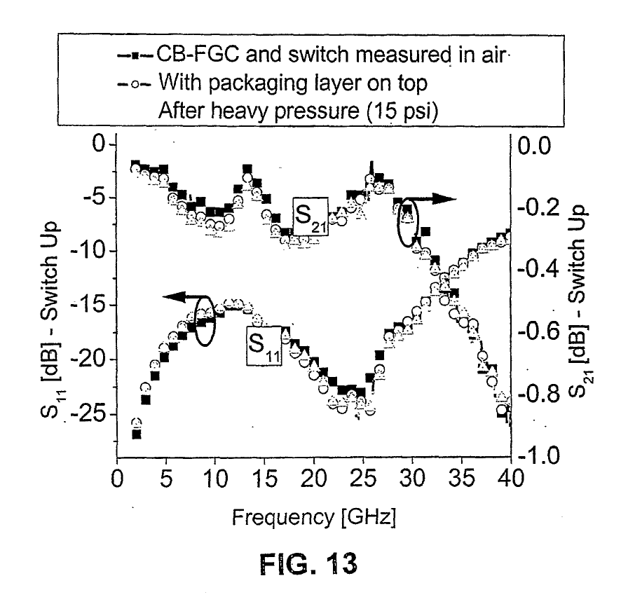

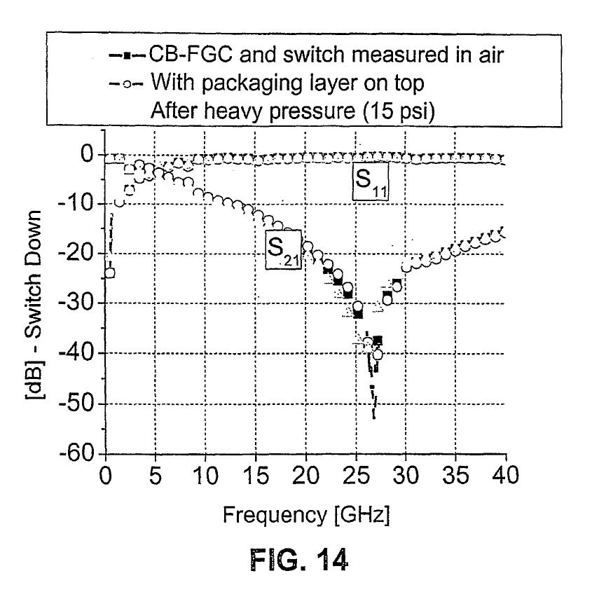

Because MEMS switches are by nature fragile, an iterative measurement procedure was undertaken. First, the switches were measured in air to provide a base measurement case. The second and third measurements were done with the package layer aligned and held into contact with the base substrate. The first packaging iteration was done by gently holding the package layer down over the MEMS substrate with tape. When the switches continued to operate with the package layer in place, this ensured that the alignment of the package cavities was successful. Finally, the top metal plate was placed over the alignment pins and a fifteen pound weight was balanced on top of the samples (see FIG. 12) to simulate the pressure from a bonding process. The plate was removed and the samples were re-measured. Results for these measurements are seen in FIGS. 13 and 14.

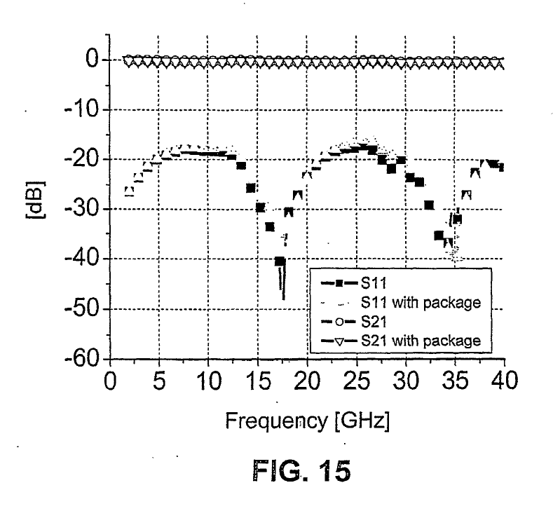

In an actual bonding process for this particular package, a hole could be cut in a low-melt 1 mil LCP bond ply to form a 1 mil (25 μm) cavity, which would require a hole to be drilled in the bond ply rather than a depth-controlled cavity in a core layer. (see FIG. 15).

Specifically, FIG. 13 presents a comparison of S-parameter measurements of an air-bridge type CB-FGC MEMS switch in the “UP” state. Case 1: The switch is measured in open air. Case 2: The packaging layer is brought down and taped into hard contact and measured. Case 3: A top metal press plate and a fifteen pound weight are put on top of the packaging layer (15 psi) to simulate bonding pressure. The weight and the press plate are then removed and the switch is re-measured.

FIG. 14 presents a comparison of S-parameter measurements of an air-bridge type CB-FGC MEMS switch in the “DOWN” state. The three measurement cases shown are the same as those explained with respect to FIG. 13.

The S-parameters of the packaged switch and the non-packaged switch are nearly identical in both the up and down states. For example, the variation between the three measurement cases for S₂₁ in the UP state only varies by an average of 0.032 dB across the entire measurement.

To show the effects of the packaging layer and cavity on a simple transmission line, the switch membrane was physically removed and the circuit re-measured. The results of the bare transmission line with and without the packaging layer are shown in FIG. 15. As expected from the simulations, the cases with and without the packaging layer are very similar.

Fabrication of an embodiment of an RF MEMS switch such as mentioned above will now be described in greater detail. In particular, clamped-clamped (air-bridge-type) and clamped-free (cantilever-type) coplanar waveguide (CPW) switches with a membrane size of 100 μm×200 μm and various hinge geometries (solid and meander shaped) were fabricated on LCP substrates using a four mask low-temperature process that reduces the surface roughness and assures good switch performance.

An embodiment of the four mask process is shown in FIGS. 16A-16C. A 3 μm PI2610 polyimide is first, spun on LCP to planarize the surface and minimize the roughness (FIG. 17A). The CPW signal lines were then fabricated by evaporating Ti/Au/Ti (300 Å/5000 Å/300 Å). PECVD Si₃N₄ layer was patterned between the membrane and the signal line: A 1.8 μm thick photoresist (1813) was spin coated and patterned to create the air-gap. Ti/Au/Ti (300 Å/3000 Å/300 Å) seed layer was then evaporated and patterned and electroplated (FIG. 16B). Finally, after removing the sacrificial photoresist layer with a resist stripper, a critical point drying process was used to release the switches (FIG. 16C).

Measurements of the air-bridge type switch were taken using an Agilent 8510 network analyzer. A TRL calibration was performed to de-embed the coplanar line and transition losses. Measured results for the nitride switches with silicon substrate and LCP are shown in FIGS. 17 and 18. The pull-down voltage was measured to be 25 V. For the LCP switch, when the switch is activated, the isolation is around 20 dB at 20 GHz and C_{ON}=3 pF, while the return loss is around 0.1 dB at 20 GHz. When the switch is in the UP position, the insertion loss is around 0.08 dB at 20 GHz and C_{OFF}=35 fF; the return loss is 18 dB at 20 GHz.

For the same switch on silicon substrate, when the switch is activated, the isolation is around 17 dB at 20 GHz and C_{ON}=2 pF, while the return loss is around 0.4 dB at 20 GHz. When the switch is in the UP position, the insertion loss is around 0.8 dB at 20 GHz and C_{OFF}=25 fF; the return loss is 10 dB at 20 GHz. The deteriorated return loss of the switch on silicon is due to the thinner sacrificial layer that increases the capacitance, while the different C_{ON} between the two types of switches with different substrate is because the thickness of silicon nitride is a little different.

The measured air-bridge switches with an LCP substrate gave better insertion loss in the up state than that of the switches on the silicon substrate. The switches on LCP also gave better isolation in the down state. Additionally, due to LCP's low dielectric constant, the air/dielectric discontinuities in the packaging structures are insignificant. Thus, the package cavities can be designed almost arbitrarily without concern for their effect on RF performance. The foregoing description has been presented for purposes of illustration and description. It is not intended to be exhaustive or to limit the invention to the precise forms disclosed. Modifications or variations are possible in light of the above teachings. By way of example, the layer count, layer thicknesses, etc. can be varied and the supported devices can be placed in various locations on and/or between the layers as desired. In particular, one package technique could be used to put packages on any single layer (likely implemented as a hole in the bond ply surrounded by two solid core layers), or by having holes in multiple layers and have the layers stacked to create taller cavities.

By way of further example, although described with reference to packaging of MEMS switches, the technique aforementioned techniques could be used broadly for integrated circuit (IC) packaging, or generally for any active or passive electronic component to be packaged in a multilayer LCP topology. Due to LCP's bonding temperature around 285° C., it is possible that ICs could be packaged inside the LCP package cavity without damaging the IC.

1. A system comprising:
a first layer of liquid crystal polymer (LCP);
a first electronic component supported by the first layer; and
a second layer of LCP;
wherein the first layer and the second layer encase the first electronic components.

2. The system of claim 1, wherein the first electronic component is near-hermetically encased by the first layer and the second layer.

3. The system of claim 1, wherein the first electronic component is located in a cavity formed in the second substrate.

4. The system of claim 1, wherein the first electronic component comprises an RF MEMS switch.

5. The system of claim 4, wherein the RF MEMS switch is an air-bridge type MEMS switch.

6. The system of claim 1, wherein the first layer and the second layer are thermally bonded to near-hermetically encase the first electronic component.

7. The system of claim 1, further comprising a third layer of LCP located between the first layer and the second layer, the third layer exhibiting a lower melting temperature than melting temperatures of the first layer and the third layer such that the third layer is melted to thermally bond the first layer to the second layer.

8. The system of claim 7, further comprising means for thermally bonding the first layer and the second layer.

9. A system comprising:
a first layer of liquid crystal polymer (LCP), the first layer being substantially planar;
a first electronic component supported by and physically contacting the first layer; and
a second layer of LCP having a cavity formed therein, the cavity being sized and shaped to receive at least a portion of the electronic component therein, the first layer and the second layer being arranged in an overlying relationship with respect to each other and fixed in position with respect to each other such that the first electronic component is near-hermetically sealed within the cavity, the first electronic components being encased within the cavity by LCP of the first layer and the second layer.

10. The system of claim 9, wherein the first electronic component comprises an RF MEMS switch.

11. The system of claim 10, wherein the RF MEMS switch is an air-bridge type MEMS switch.

12. The system of claim 9, further comprising a third layer of LCP located between the first layer and the second layer, the third layer exhibiting a lower melting temperature than melting temperatures of the first layer and the third layer such that the third layer is melted to thermally bond the first layer to the second layer.

13. A method comprising:
providing a first layer and a second layer of liquid crystal polymer (LCP);
supporting a first electronic component with the first layer; and
encasing the first electronic component with the first layer and the second layer.

14. The method of claim 13, wherein encasing comprises:
providing a third layer of LCP;
arranging the third layer between the first layer and the second layer, the third layer exhibiting a lower melting temperature than melting temperatures of the first layer and the third layer; and
melting the third layer such that the first layer is thermally bonded to the second layer.

15. The method of claim 13, wherein the first electronic component is near-hermetically sealed within a cavity sandwiched between the first layer and the second layer.

16. The method of claim 13, wherein encasing comprises:
forming alignment holes through the first layer and the second layer using a laser.

17. The method of claim 16, further comprising:
cleaning the first layer and the second layer after forming the alignment holes in order to reduce surface irregularities.

18. The method of claim 16, wherein the cleaning comprises a plasma cleaning process.

19. The method of claim 13, wherein the first electronic component is an RF MEMS switch.

20. The method of claim 19, wherein the RF MEMS switch is formed by four mask process.
